(19) United States
(12) Patent Application Publication
(10) Pub. No.: US 2014/0042472 A1
(43) Pub. Date: Feb. 13, 2014

(54) SEMICONDUCTOR LIGHT-EMITTING DEVICE

(71) Applicant: KABUSHIKI KAISHA TOSHIBA, Tokyo (JP)

(72) Inventor: Mitsuhiro KOBAYASHI, Kanagawa-ken (JP)

(73) Assignee: KABUSHIKI KAISHA TOSHIBA, Tokyo (JP)

(21) Appl. No.: 13/778,489

(22) Filed: Feb. 27, 2013

(30) Foreign Application Priority Data
Aug. 8, 2012 (JP) 2012-175842

(51) Int. Cl. H01L 33/56

(52) U.S. Cl. CPC H01L 33/56
USPC 257/98

(57) ABSTRACT

A semiconductor light-emitting device includes a substrate, a semiconductor light-emitting element, a frame body, a first translucent resin, and a second translucent resin. The substrate has a convex portion. The semiconductor light-emitting element placed on the convex portion. The frame body is provided so as to surround the convex portion. The first translucent resin covers an upper surface and a side surface of the light-emitting element, extends from the convex portion to the frame body, and contains a fluorescent body. The second translucent resin is provided on the substrate so as to bury the light-emitting element and the frame body.

### CROSS REFERENCE TO RELATED APPLICATION

This application is based upon and claims the benefit of priority from the prior Japanese Patent Application No. 2012-175842, filed on Aug. 8, 2012, the entire contents of which are incorporated herein by reference.

### FIELD

Embodiments described herein generally relates to a semiconductor light-emitting device.

### BACKGROUND

In the background art, some semiconductor light-emitting devices have included a nitride semiconductor light-emitting element and translucent resin. The element is mounted at a lead frame and bonded to the lead frame. The translucent resin containing a fluorescent body is provided on the lead frame so as to bury the light-emitting element.

A semiconductor white-light-emitting device is provided by combining a blue-light-emitting element with yellow-light-emitting translucent resin containing a fluorescent body absorbing blue light.

Blue light emitted from the element passes through the resin. The fluorescent body absorbs a portion of the blue light during the pass to convert the portion into yellow light. Remaining blue light except the portion is emitted outside. A ratio of the intensity of the yellow light to the blue light emitted outside depends on a distance that the blue light traveled inside the translucent resin. The longer the distance, the higher the intensity of the yellow light, the lower the intensity of the blue light.

As a result, blue light and yellow light are different from each other in intensity distribution. The ratio of the intensity of the yellow light to the blue light changes with a light distribution angle. Unfortunately, the light-emitting devices of the background art show large variations in the chromaticity of light with a viewing direction.

### BRIEF DESCRIPTION OF THE DRAWINGS

FIGS. 1A and 1B are views showing a semiconductor light-emitting device according to a first embodiment.

FIG. 2 is a sectional view showing a semiconductor light-emitting device according to a comparative example.

FIGS. 3A and 3B are views showing angular dependence of chromaticity of the semiconductor light-emitting device according to the first embodiment in comparison with the chromaticity of the semiconductor light-emitting device according to the comparative example.

FIG. 4 is a view for explaining the chromaticity of the semiconductor light-emitting element according to the first embodiment.

FIGS. 5A to 5C and FIGS. 6A to 6C are sectional views showing steps of manufacturing the semiconductor light-emitting device according to the first embodiment in sequence.

FIGS. 7 and 8 are sectional views showing semiconductor light-emitting devices according to the first embodiment, both emitting light focused in one direction.

FIG. 9 is a sectional view showing another semiconductor light-emitting device according to the first embodiment.

FIGS. 10A and 10B are views showing a semiconductor light-emitting device according to a second embodiment.

FIG. 11 is a sectional view showing another semiconductor light-emitting element according to the second embodiment.

FIG. 12 is a sectional view showing another semiconductor light-emitting element according to the second embodiment.

FIG. 13 is a sectional view showing another semiconductor light-emitting element according to the second embodiment.

FIGS. 14A and 14B are views showing a main portion of a semiconductor light-emitting device according to a third embodiment.

FIGS. 15A to 15C are views showing main portions of semiconductor light-emitting devices according to a fourth embodiment.

### DETAILED DESCRIPTION

According to an embodiment, a semiconductor light-emitting device includes a substrate, a semiconductor light-emitting element, a frame body, a first translucent resin, and a second translucent resin. The substrate has a convex portion. The semiconductor light-emitting element placed on the convex portion. The frame body is provided so as to surround the convex portion. The first translucent resin covers an upper surface and a side surface of the light-emitting element, extends from the convex portion to the frame body, and contains a fluorescent body. The second translucent resin is provided on the substrate so as to bury the light-emitting element and the frame body.

An embodiment will be described with reference to drawings. In the drawing, the same reference numerals denote the same or similar portions.

### First Embodiment

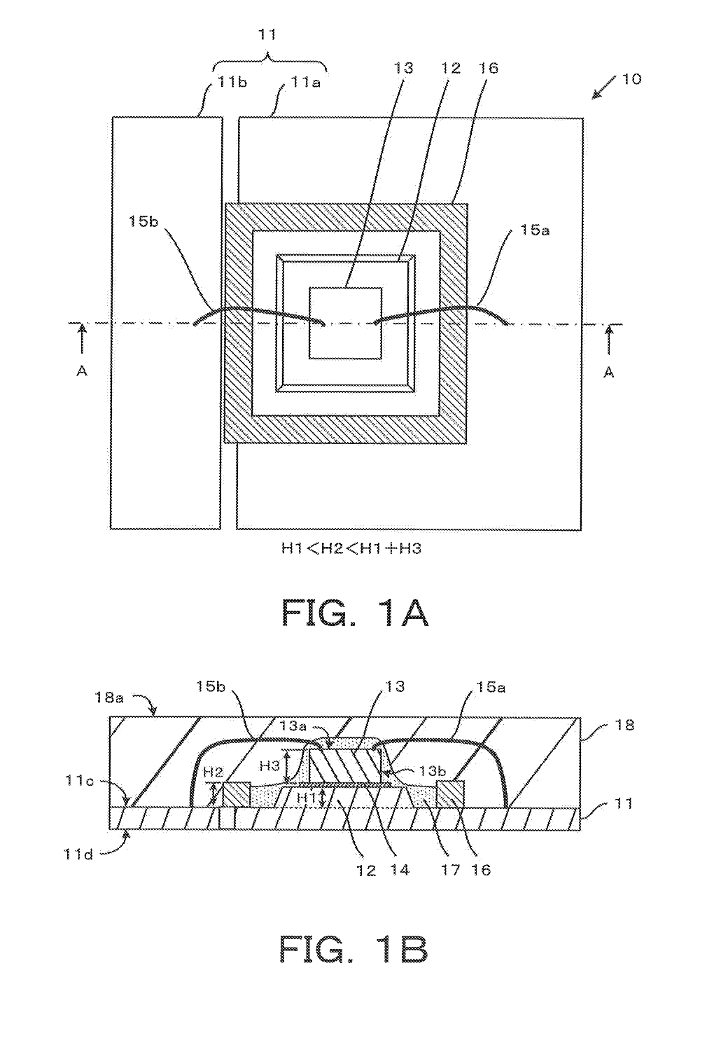

A semiconductor light-emitting device in accordance with a first embodiment will be described with reference to FIGS. 1A and 1B. FIGS. 1A and 1B are views showing the semiconductor light-emitting device of the embodiment. FIG. 1A is a plan view of the device. FIG. 1B is a sectional view taken along the A-A line of FIG. 1A, viewed from the arrows.

The semiconductor light-emitting device includes a nitride semiconductor light-emitting element and translucent resin to emit white light, in the device, the resin containing a fluorescent body conformally covers the blue-light-emitting element to mold the element. The fluorescent body absorbs blue light emitted from the element to emit yellow light. As a result, the device is capable of emitting white light.

As shown in FIGS. 1A and 1B, the semiconductor light-emitting device 10 includes a conductive substrate 11. The substrate 11 has a first substrate 11a and a second substrate 11b, both being rectangular in shape and arranged with their sidewalls facing each other. The first substrate 11a is provided with a convex portion 12 having a height H1 from an upper surface 11c.

The convex portion 12 has a sloped side surface, and the cross section thereof is trapezoidal in shape. The convex portion 12 serves as a base to place a semiconductor light-emitting element 13.

The semiconductor light-emitting element 13 is placed on the convex portion 12 to be fixed thereon with an adhesive 14. The semiconductor light-emitting element 13 has first-electrode and second-electrode terminals (both not shown) on an upper surface 13a. The first-electrode, terminal is electrically connected to the first substrate 11a through a wire 15a. The second electrode terminal is electrically connected to the second substrate 11b through a wire 15b.

A frame body 16 with a height H2 from the upper surface 11c is provided so as to surround the convex portion 12.

A first translucent resin 17 containing a fluorescent body (not shown) covers the upper surface 13a and the side surface 13b of the semiconductor light-emitting element 13, and extends to the frame body 16 from the convex portion 12. The first translucent resin 17 has a redundant portion that does not cover the semiconductor light-emitting element 13, and the redundant portion falls into a space between the convex portion 12 and the frame body 16.

The second translucent resin 18 is provided so as to bury the semiconductor light-emitting element 13 covered with the first translucent resin 17.

The semiconductor light-emitting device 10 will be specifically described. The substrate 11 is a copper or iron plate with a thickness of 200 μm, and is plated with Ni. The convex portion 12 is formed by processing a portion of the substrate 11, and the height H1 is about 100 μm, for example.

The semiconductor light-emitting element 13 is an InGaN-series semiconductor light-emitting element, which emits blue light with a wavelength of about 450 nm, for example. The semiconductor light-emitting element 13 is 500 μm in width and 100 to 150 μm in thickness, for example.

The semiconductor light-emitting element 13 in turn includes a sapphire substrate, an N-type GaN clad layer, a semiconductor light-emitting layer, a P-type GaN clad layer, and a P-type GaN contact layer, all of which are laminated. The semiconductor light-emitting layer includes a multiple quantum well structure with in GaN well layers and GaN barrier layers each laminated alternately.

The semiconductor light-emitting element 13 has a notch (not shown) for exposing the N-type GaN clad layer. A first electrode (P-side electrode) terminal is provided on the P-type GaN contact layer. A second electrode (N-side electrode) terminal is provided on the N-type GaN clad layer, which is exposed at the notch.

The first electrode terminal is made up of a gold (Au) film enabling an ohmic contact with a P-type GaN layer. The second electrode terminal is made up of a laminated film of titanium (Ti)/platinum (Pt)/gold (Au). The laminated film enables an ohmic contact with an N-type GaN layer. The first electrode terminal is an anode terminal. The second electrode terminal is a cathode terminal.

The frame body 16 is made up of white resin, for example. The white resin is epoxy resin containing much inorganic filler, such as titanium oxide (TiO₂), for example. When the frame body 16 is too short, the first translucent resin 17 will overflow outside the frame body 16. When the frame body 16 is too tall, the frame body 16 blocks light emitted from the semiconductor light-emitting element 13.

Preferably, the frame body 16 has a height as low as possible. Specifically, the height of the frame body 16 is not less than a height H1 of the convex portion 12 and not more than the sum of the height H1 and the thickness H3 of the semiconductor light-emitting element 13. The frame body 16 appropriately has a height of about 100 to 120 μm.

The first translucent resin 17 is made up of epoxy resin, silicone resin, or acrylic resin, all of which are translucent. The first translucent resin 17 contains the fluorescent body by 40 to 50 wt %.

A fluorescent body is a YAG (yttrium/aluminum/garnet) fluorescent body to emit yellow light by absorbing blue light. The YAG fluorescent body is expressed by the following general formula.

The formula is (RE₁₋ₓSmₓ)₃(AlyGa_{1-y})₅O₁₂:Ce, assuming that 0≦x≦1, 0≦y≦1, and RE is at least one element selected from Y and Gd.

The second translucent resin 18 has a shape of a rectangular parallelepiped with an upper surface 18a that is parallel to a plane including the substrate 11. The second translucent resin 18 buries the semiconductor light-emitting element 13 covered with the first translucent resin 17 and the wires 15a and 15b in the resin. The second translucent resin 18 covers the upper surface 11c of the substrate 11, but does not cover the lower surface 11d.

In the semiconductor light-emitting device 10, the first electrode terminal of the semiconductor light-emitting element 13 is extracted to the first substrate 11a, and the second electrode terminal is extracted to the second substrate 11b. When the first substrate 11a is connected to a positive terminal of a power supply and when the second substrate 11b is connected to a negative terminal of the power supply, current flows through the semiconductor light-emitting element 13 to permit the element 13 to emit blue light.

The fluorescent body absorbs a portion of the emitted blue light to emit yellow light. The remaining portion of the emitted blue light, which has not been absorbed by the fluorescent body, is mixed with the yellow light emitted from the fluorescent body to make white light.

The convex portion 12 makes a difference in height between the upper surface of the substrate 11 and the surface on which the element 13 is placed. The difference enables the above-mentioned semiconductor light-emitting device 10 to be conformally covered with the first translucent resin 17

The semiconductor light-emitting device 10 stores an excess of the first translucent resin 17 in the inside area of the frame body 16 to prevent an adverse effect from an outflow of the first translucent resin 17, and thus facilitates fabrication of the device 10.

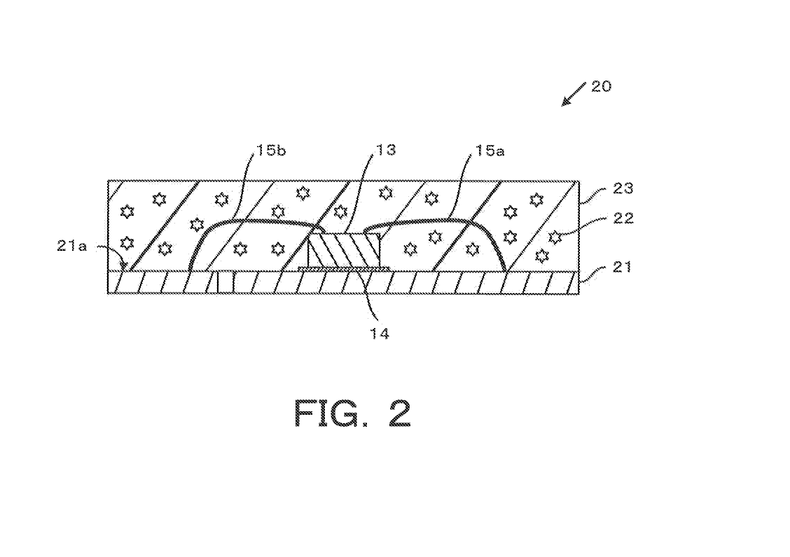

Chromaticity of the semiconductor light-emitting device 10 of the first embodiment will be described in comparison with a semiconductor light-emitting device of a comparative example. First, the semiconductor light-emitting device of the comparative example will be described. FIG. 2 is a sectional view showing the semiconductor light-emitting device of the comparative example.

As shown in FIG. 2, a semiconductor light-emitting device 20 of the comparative example has a semiconductor light-emitting element 13 that is placed on an upper surface 21a of a flat substrate 21 to be fixed thereon with an adhesive 14. A translucent resin 23 containing fluorescent bodies 22 has a shape of rectangular parallelepiped, and is provided so as to bury the semiconductor light-emitting element 13 therein.

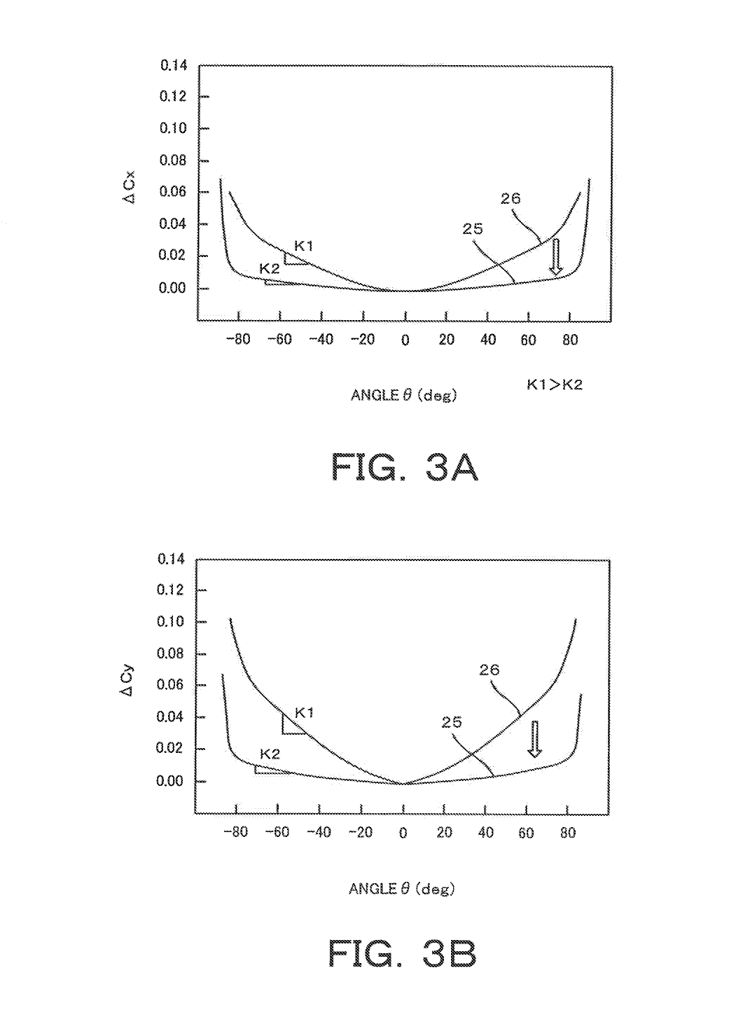

FIGS. 3A and 3B are views showing angular dependence of the chromaticity of the semiconductor light-emitting device 10 in comparison with that of the semiconductor light-emitting device 20. FIG. 3A is a view showing a relation between an angle θ and a rate ΔCx in a chromaticity coordinate x. FIG. 3B is a view showing a relation between the angle θ and a rate ΔCy in a chromaticity coordinate y.

In FIG. 3, the solid line 25 shows the angular dependence of the chromaticity of the semiconductor light-emitting device 10 of the first embodiment, and the solid line 26 shows the angular dependence of the chromaticity of the semiconductor light-emitting element 20 of the comparative example. An angle of θ° denotes viewing the semiconductor light-emitting devices from directly above, and an angle of ±90° denotes viewing the semiconductor light-emitting devices just from the lateral direction.

The following formula is established as

(ΔCx,ΔCy)=(Cxθ−Cx0,Cyθ−Cy0),

provided that the chromaticity coordinate at an angle of 0° is expressed as (Cx0, Cy0), and the chromaticity coordinate at an angle of θ is expressed as (Cxθ, Cyθ). For example, “ΔCx=0.025 at θ=60°” and “ΔCy=0.045 at θ=60°” are established on the solid line 26.

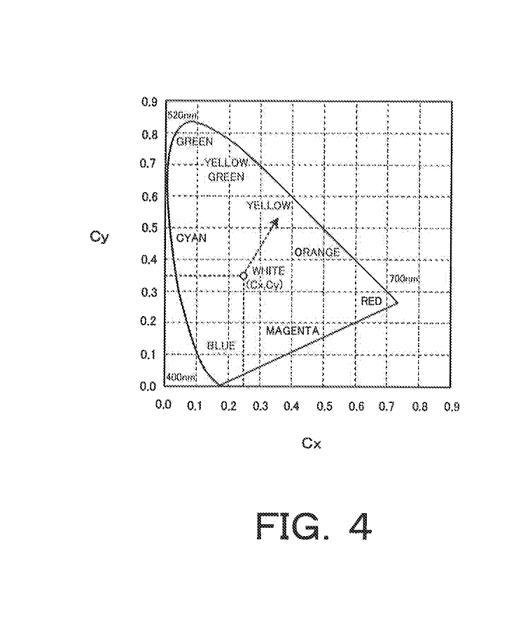

FIG. 4 is a view for explaining the chromaticity of the semiconductor light-emitting element in accordance with the first embodiment. The chromaticity coordinate of white light at θ=0° is assumed to be (0.25, 0.35), for example. The chromaticity coordinate at θ=60° on the solid line 26 is specified as (0.275, 0.395).

The intensity ratio of blue light to yellow light varies at θ=60° with respect to θ=0°. The relative intensity of yellow light at θ=60° is higher than the intensity thereof at θ=0°, meaning that the chromaticity coordinate (Cx, Cy) shifts in the direction denoted by the arrow (yellow shift) in FIG. 4. In this case, white light looks yellow-tinged.

The angular dependence of the chromaticity arises from a difference in the distance that blue light travels in the translucent resin containing the fluorescent body. The longer the distance, the more the blue light is absorbed by the fluorescent body to be converted into yellow light.

In contrast, the shorter the distance, the less the blue light is absorbed by the fluorescent body to be emitted as it is. As a result, the ratio of blue light to yellow light changes with the angle θ.

As shown in FIGS. 3A and 3B, the semiconductor light-emitting element 20 of the comparative example shows the angular dependence where ΔCx and ΔCy increase with the angle θ nearly symmetrically both in the positive and negative axes. ΔCx and ΔCy increase by a first gradient K1 at angles approximately ranging from 20′ to 70°. When the angle 0 exceeds 70′, ΔCx and ΔCy increase rapidly.

Meanwhile, the semiconductor light-emitting element 10 of the first embodiment shows the same tendency as the semiconductor light-emitting element 20 of the comparative example. The tendency is that ΔCx and ΔCy increase with the angle θ nearly symmetrically both in the positive and negative axes. The gradients of ΔCx and ΔCy, however, differ from each other at low angles, and the angles at which ΔCx and ΔCy increase rapidly also differ from each other.

ΔCx and ΔCy increase by a second gradient K2 lower than the first gradient K1 until the angle 0 reaches about ±80. The first gradients K1 of ΔCx and ΔCy are five times as high as the second gradients K2 thereof. ΔCx and ΔCy increase rapidly when the angle θ exceeds 80°.

The angular dependence of the chromaticity of the semiconductor light-emitting device 10 has been revealed to be much less than that of the semiconductor light-emitting device 20.

In the semiconductor light-emitting element 20, the translucent resin 23 containing the fluorescent bodies 22 has various thicknesses depending on directions. The translucent resin 23 is thicker in a direction parallel to the substrate than in a direction perpendicular thereto. That is, the fluorescent bodies 22 seem to be contained more in the direction parallel to the substrate than in the direction perpendicular thereto when viewed from the semiconductor light-emitting element 13.

As a result, blue light emitted from the semiconductor light-emitting element 13 has various probabilities for colliding with fluorescent bodies 22. The probabilities depend on the direction in which the blue light travels. A large difference in the intensity ratio of blue light to yellow light causes variations in the chromaticity (color breakup), depending on the viewing directions.

By contrast, the semiconductor light-emitting element 13 is thinly covered with the first translucent resin 17 at the upper surface 13a and the side surface 13b in the semiconductor light-emitting device 10. In other words, the element 13 is conformally covered with the first translucent resin 17 by a substantially equivalent thickness. The fluorescent bodies distribute around the element 13 when the fluorescent bodies are viewed from the element 13.

As a result, blue light emitted from the semiconductor light-emitting element 13 has an equal probability for colliding with the fluorescent bodies independently of the traveling directions (viewing directions). Variations in the chromaticity with viewing directions are, therefore, enabled to decrease. Causing the chromaticity of blue light to approach the chromaticity of yellow light enables it to reduce the variations in the chromaticity with viewing directions.

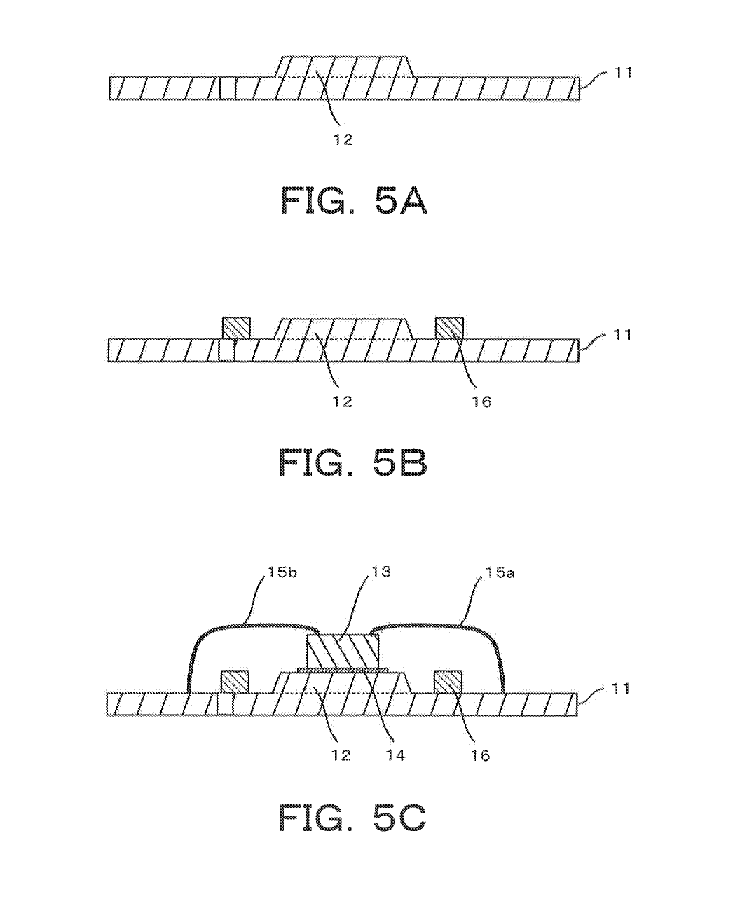

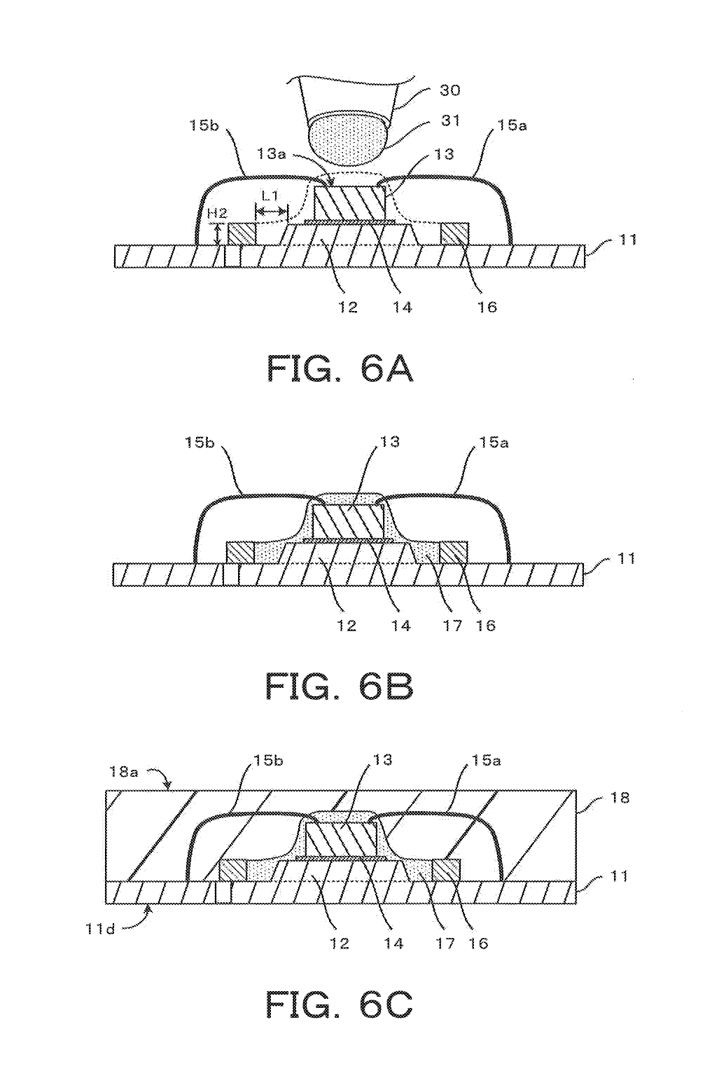

A method for manufacturing the semiconductor light-emitting device 10 will be described. FIGS. 5A to 5C and FIGS. 6A to 6C are sectional views showing steps of manufacturing the semiconductor light-emitting device 10 in sequence.

As shown in FIG. 5A, the substrate 11 with the convex portion 12 is prepared. The convex portion 12 is formed by pressing the substrate 11 with a metallic mold or by masking a convex-portion-12-forming region to etch the region.

As shown in FIG. 5B, the frame body 16 is formed so as to surround the convex portion 12. The frame body 16 is beforehand made up with a metallic mold to be fixed on the substrate with an adhesive (not shown). Liquid white resin is applied to the substrate 11 in a frame-like pattern with a dispenser to form the frame body 16 by curing the liquid white resin applied.

As shown in FIG. 5C, the semiconductor light-emitting element 13 is placed on the convex portion 12 with the adhesive 14. The one end portion of the wire 15a is bonded to the first electrode terminal, and the other end portion of the wire 15a is bonded to the substrate 11a. The one end portion of the wire 15b is bonded to the second electrode terminal, and the other end portion of the wire 15b is bonded to the substrate 11b.

As shown in FIG. 6A, the liquid translucent resin 31 containing fluorescent bodies is dripped on the upper surface 13a of the semiconductor light-emitting element 13 using a dispenser 30 (potting). A drip amount of the liquid translucent resin 31 may be set to be more than an amount necessary (hereinafter referred to as a covering amount) to cover the upper surface 13a and the side surface 13b of the semiconductor light-emitting element 13.

As shown by the dashed line, the translucent resin 31 covers the upper surface 13a of the semiconductor light-emitting element 13 in a convex. The translucent resin 31 also covers the side surface 13b of the semiconductor light-emitting element 13 in a skirt shape. An excess of the translucent resin 31 does not cover the semiconductor light-emitting element 13, and falls along a sloped surface of the convex portion 12 to reach the frame body 16. The excess is stored between the convex portion 12 and the frame body 16.

The covering amount depends on a balance between the weight and viscosity of the translucent resin 31 and depends on the friction against the surface to which the resin 31 is applied. A storable amount to store the excess between the convex portion 12 and the frame body 16 depends on the height H2 of the frame body 16 and a distance L1 from the convex portion 12 to the frame body 16.

A drip amount of the translucent resin 31 is not less than a covering amount of the translucent resin 31, and not more than the sum of the covering amount and the storable amount of the translucent resin 31 therebetween. As a result, the drip amount of the translucent resin 31 is easily controlled, thereby enabling it to cover the upper surface 13a and the side surface 13b of the semiconductor light-emitting element 13 with the translucent resin 31.

As shown in FIG. 6B, the dripped translucent resin 31 is cured at a predetermined temperature. As a result, the first translucent resin 17 covers the upper surface 13a and the side surface 13b of the semiconductor light-emitting element 13 to extend from the convex portion 12 to the frame body 16.

As shown in FIG. 6C, the dispenser (not shown) is used to inject liquid translucent resin (not shown), e.g., epoxy resin, into a metallic mold (not shown) with a box-like concave portion. The substrate 11 is reversed, the semiconductor light-emitting element 13 is stored at the concave portion of the metallic mold, and the epoxy resin is cured at a predetermined temperature.

The cured epoxy resin is ejected from the metallic mold. A second translucent resin 18 is formed on the substrate 11 so as to bury the semiconductor light-emitting element 13 within the second translucent resin 18. The second translucent resin 18 has an upper surface 18a substantially parallel to the substrate 11, while the lower surface 11d of the substrate 11 is exposed. As a result, the semiconductor light-emitting device 10 shown in FIGS. 1A and 1B is obtained.

As described above, the first embodiment includes the convex portion 12 and the frame body 16 surrounding the convex portion 12. The semiconductor light-emitting element 13 is placed on the convex portion 12, the translucent resin 31 containing fluorescent bodies is dripped over the semiconductor light-emitting element 13 to cover the element 13, and the first translucent resin 17 is provided so as to extend from the convex portion 12 to the frame body 16.

As a result, the chromaticity of blue light from the semiconductor light-emitting element 13 is enabled to be similar to the chromaticity of yellow light from the first translucent resin 17 containing fluorescent bodies. The semiconductor light-emitting element is, therefore, achieved to have little variations in the chromaticity with a viewing direction.

The excess of the translucent resin 31 which does not cover the semiconductor light-emitting element 13 is stored between the convex portion 12 and the frame body 16, and is not in contact with the wires 15a and 15b. Thus, the wires 15a and 15b do not undergo deformation due to resin stress occurring when the translucent resin 31 is cured.

The adhesion between the substrate 11 and the second translucent resin 18 does not lower because the first translucent resin 17 (cured translucent resin 31) is not inserted between the substrate 11 and the second translucent resin 18.

In the above description, just one semiconductor light-emitting element 13 is placed on the convex portion 12. Alternatively, two or more semiconductor light-emitting elements 13 may be placed on the convex portion 12. The semiconductor light-emitting element 13 may be an aggregate including two or more semiconductor light-emitting elements.

Placing two or more semiconductor light-emitting elements on the convex portion 12 reduces variations in the chromaticity with a viewing direction to achieve a semiconductor light-emitting device of COB (Chip On Board) type with high light output.

Excessive numbers of semiconductor light-emitting elements on the convex portion 12 are likely to cause the first translucent resin 17 to be stored between adjacent semiconductor light-emitting elements. In such a case, two or more convex portions 12 may be provided. All that is required for frame body 16 is to surround the convex portions 12.

The fluorescent bodies are YAG fluorescent bodies in the above description, but not limited to the YAG ones. Alternatively, the fluorescent bodies may be sialon-series red fluorescent bodies or sialon-series green fluorescent bodies. Alternatively, the fluorescent bodies may be a composite including two or more kinds of fluorescent materials, which emit light with wavelengths that are different from one another.

Mixing blue light properly with yellow light, red light, and green light also reduces variations in the chromaticity with a viewing direction to achieve a semiconductor light-emitting element which emits light of neutral colors.

In the above description, the second translucent resin 18 is clear resin. Alternatively, the second translucent resin 18 may be smoke resin containing a diffusion agent, which diffuses light emitted from the semiconductor light-emitting element 13 and light emitted from the fluorescent body. Examples of a diffusion agent include silica (SiO₂) and zirconia (ZrO₂). The diffusion agent achieves a semiconductor light-emitting device having little variations in the chromaticity with a viewing direction and emitting diffusion light. The first translucent resin 17 may contain a diffusion agent that diffuses light from the semiconductor light-emitting element 13 and light from a fluorescent body. The diffusion agent of the first translucent resin 17 may be the same as the diffusion agent of the second translucent resin 18. It is suitable to use a diffusion agent that diffuses light from a fluorescent body more strongly than light from the semiconductor light-emitting element 13. Diffusing light from the fluorescent body preferentially has a merit to cause chromaticity the characteristic of blue light to approach the chromaticity of yellow light.

In the above description, the semiconductor light-emitting device 10 includes the second translucent resin 18 being rectangular parallelepiped-like in shape to emit light from the upper surface and side surface of the second translucent resin 18. The semiconductor light-emitting device 10 may be modified to emit light focused in one direction. The semiconductor light-emitting element 10 has little variations in the chromaticity with a viewing direction, and emits highly directional light.

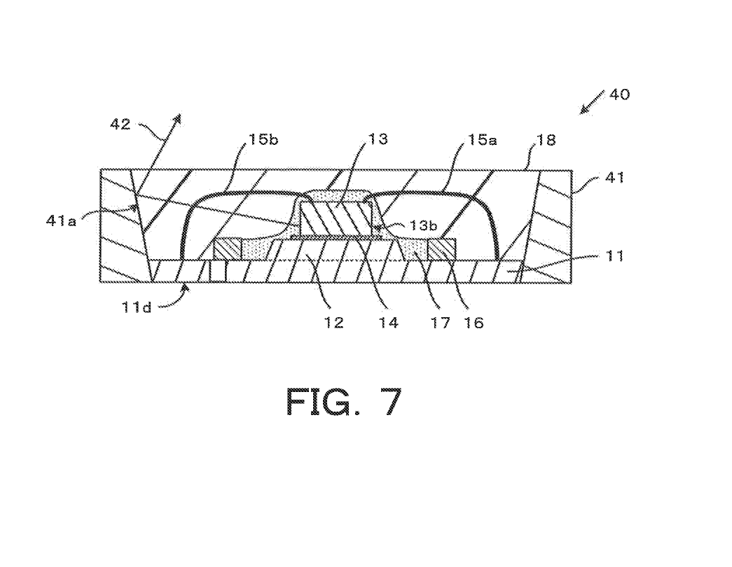

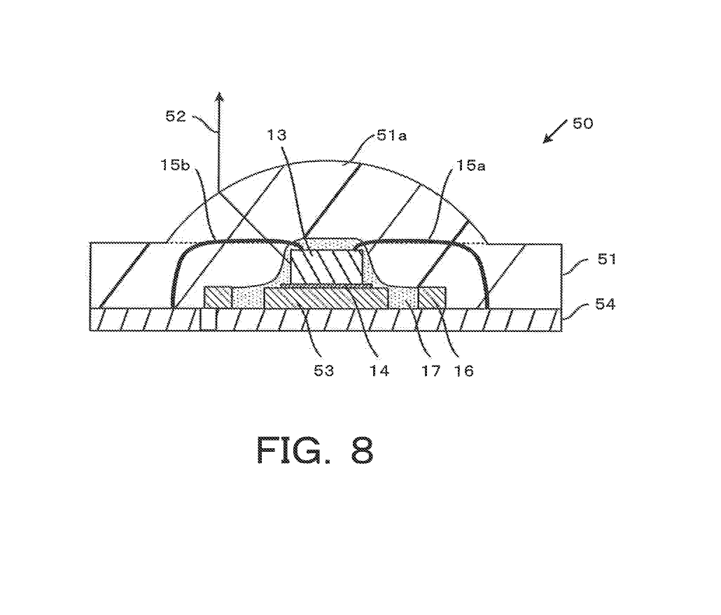

FIGS. 7 and 8 are sectional views showing semiconductor light-emitting devices, both emitting light focused in one direction. As shown in FIG. 7, a semiconductor light-emitting device 40 is provided with a case 41 at an outer circumference of the substrate 11. The case 41 has an opening enlarging from the substrate 11 toward the semiconductor light-emitting element 13. The case 41 is what is called a mortar-like case.

The semiconductor light-emitting element 13 is arranged at the bottom of the opening of the case 41. The frame body 16 prevents the liquid translucent resin 31 from flowing out and climbing a slope 41a of the case 41.

The aperture of the case 41 is filled with the second translucent resin 18 by potting. The case 41 does not cover the lower surface of the substrate 11. The case 41 made up of light-blocking resin, ceramics or the like.

Light 42 is emitted from the side surface 13b of the semiconductor light-emitting element 13, and enters the case 41. Most of the light 42 is reflected by the slope 41 to be focused in one direction.

As shown in FIG. 8, a semiconductor light-emitting device 50 includes a second translucent resin 51 with a dome-like convex portion. 51a. The dome-like convex portion 51a serves as a lens. Light 52 is emitted from the semiconductor light-emitting element 13 to travel for the dome-like convex portion 51a. The light 52 is refracted by the dome-like convex portion 51a to be focused in one direction.

In addition, the semiconductor light-emitting device 50 includes a submount substrate 53 as a convex portion of a substrate. The submount substrate 53 is mounted on the flat substrate 54 with adhesives (not shown).

Various materials can be used for the submount substrate 53. An alumina ceramic substrate with high heat conductivity is used as an electrically insulating substrate. A silicon substrate or a metal substrate is used as an electrically conducting substrate, for example.

The semiconductor light-emitting device 50 may include a protection diode to protect the semiconductor light-emitting element 13 from ESD (Electro Static Discharge). The protection diode can be used as the submount substrate 53. The protection diode is a zener diode, for example.

FIGS. 7 and 8 each show nothing more than an example of a package for the semiconductor light-emitting device. Other various packages may be used.

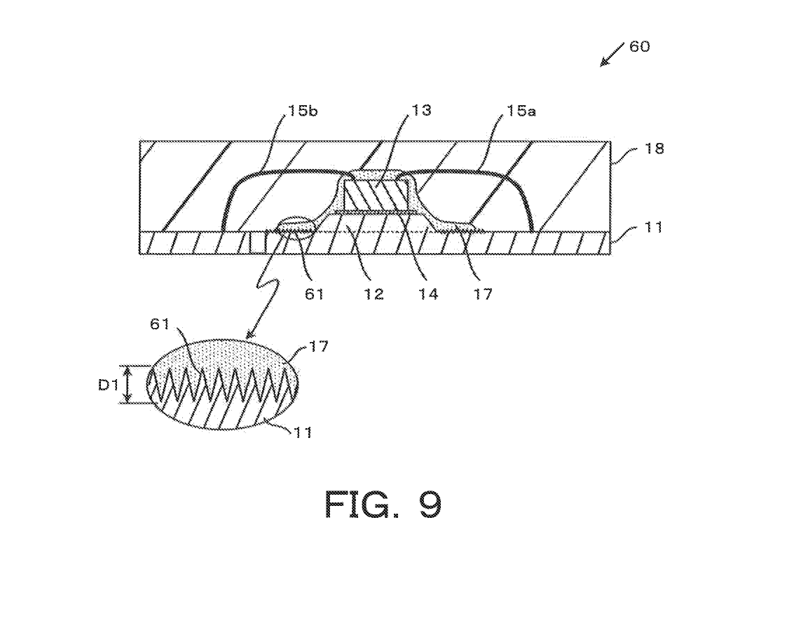

In the above description, the frame body 16 is used to capture excessive liquid translucent resin 31. Other bodies may be used as long as the bodies are capable of capturing the excessive resin. FIG. 9 is a sectional view showing a semiconductor light-emitting device including a concavo-convex portion around the convex portion 12.

As shown in FIG. 9, a concavo-convex portion 61 is provided on the substrate 11 so as to surround the convex portion 12. The concavo-convex portion 61 is adjacent to the outer circumference of the convex portion 12. The concavo-convex portion 61 traps the translucent resin 61 having run down from the convex portion 12 to prevent the translucent resin 31 from unnecessarily flowing out.

A region around the convex portion 12 of the substrate 11 is roughed to form the concavo-convex portions 61 by pressing, etching, sandblasting, and cutting. The depth D1 of the concavo-convex portion 61 is much smaller than the height H1 of the convex portion 12.

For this reason, the concavo-convex portion 61 has a smaller storable amount of the translucent resin 31 than the frame body 16. The semiconductor light-emitting device 60 is suitable for a comparatively small semiconductor light-emitting element 13 and a small drip amount of the translucent resin 31.

In the above description, the semiconductor light-emitting element 13 has the first and second electrode terminals on the upper surface 13a, but is not limited to the structure. A semiconductor light-emitting element with electrode terminals on upper and lower surfaces of the element (vertical energization type) may be used. A semiconductor light-emitting element of a flip chip type may be used.

The semiconductor light-emitting element of vertical energization type has one of the first and second electrode terminals on the upper surface and the other on the lower surface.

The semiconductor light-emitting element of vertical energization type is mounted on the convex portion 12 with a conductive adhesive to eliminate the need for one of the two wires. Examples of the vertical energization type include a semiconductor light-emitting element formed on a GaN substrate or a SiC substrate.

In the above description, the substrate 11 is a metal plate. A lead frame may be used for the substrate 11. When a substrate is a lead frame, a semiconductor light-emitting device of PLCC (Plastic Lead Chip Carrier) type is acquired.

In the above description, the frame body 16 is made up of white resin. The frame body 16 may be made up of translucent resin. When the frame body 16 is made up of the translucent resin, the frame body 16 has no upper limit of the height thereof because the frame body 16 does not block light emitted from the semiconductor light-emitting element 13.

In the above description, the semiconductor light-emitting device emits white light by converting blue light into the white light. It is also possible to compose a light-emitting device capable of emitting white light by using a semiconductor light-emitting element that emits ultraviolet.

### Second Embodiment

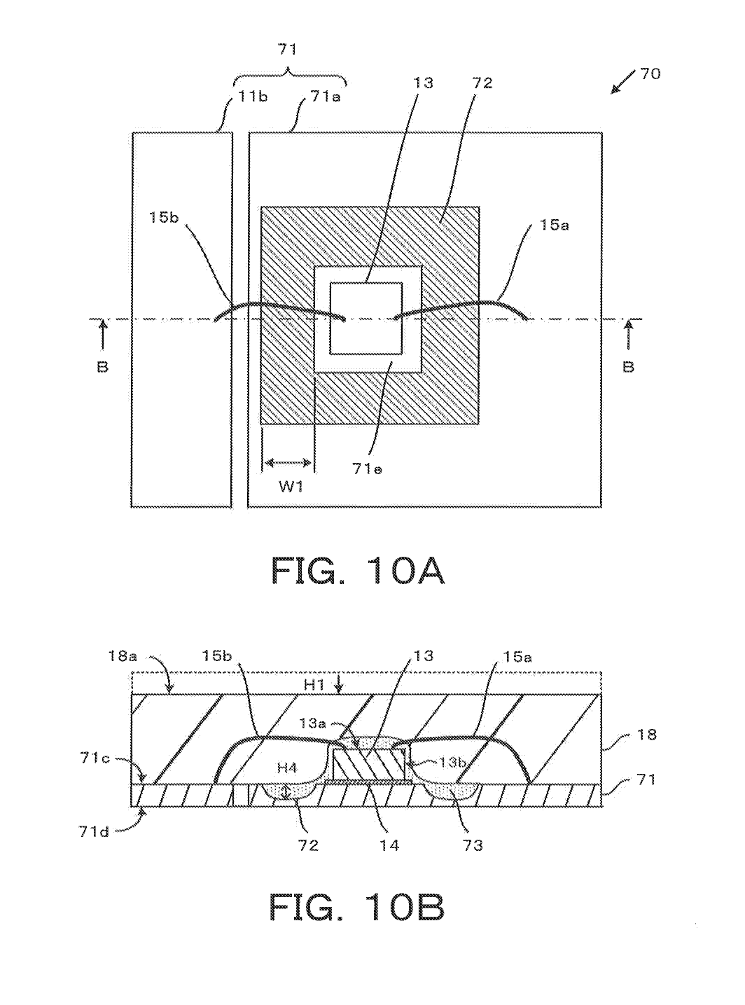

A semiconductor light-emitting device in accordance with a second embodiment will be described with reference to FIGS. 10A and 10B. FIG. 10A is a plan view showing the semiconductor light-emitting device of the second embodiment. FIG. 10B is a sectional view cut along the B-B line in FIG. 10A, viewed from the direction denoted by the arrows.

The same portions or the like will be denoted by the same reference numerals also in the second embodiment. The same explanations will not be repeated. The second embodiment differs from the first embodiment in that the second embodiment includes a closed-path-like concave portion.

As shown in FIGS. 10A and 10B, a semiconductor light-emitting device 70 of the second embodiment includes a closed-path-like concave portion 72 in an upper surface 71c of a first substrate 71a of a substrate 71. The concave portion 72 is formed in the form of a frame-like trench, for example. The concave portion 72 is formed by pressing or etching the substrate 71.

The semiconductor light-emitting element 13 is placed on a region 71e surrounded by the concave portion 72 with the adhesives 14.

A first translucent resin 73 containing a fluorescent body (not shown) covers the upper surface 13a and the side surface 13b of the semiconductor light-emitting element 13. The first translucent resin 73 covering the upper surface 13a and the side surface 13b of the semiconductor light-emitting element 13 extends from the region 71 to the concave portion 72.

An excess of the first translucent resin 73, which does not cover the semiconductor light-emitting element 13, is stored in the concave portion 72.

The product of a width W1 and a height H4 is set as to be equal to the product of a distance L1 and a height H2. The W1 and the height H4 are of the convex portion 12. The distance L1 is a distance from the convex portion 12 to the frame body 16. Both the distance L1 and the height H2 of the frame body 16 are shown in FIGS. 6A to 6C. A storable amount of the concave portion 72 for the liquid translucent resin 31 is set so as to be substantially equal to a storable amount of the frame body 16 therefore.

The above-mentioned semiconductor light-emitting device 70 places the semiconductor light-emitting element 13 on the region 71e surrounded by the concave portion 72 of the substrate 71 to store the excess of the translucent resin 31 in the concave portion 72, such that the first translucent resin 73 covers the upper surface 13a and the side surface 13b of the semiconductor light-emitting element 13.

As a result, variations in the chromaticity with a viewing direction are reduced, and the first translucent resin 73 is prevented from flowing out. The semiconductor light-emitting device 70 enables it to downsize the device 70 by the height 111 of the convex portion 12 in comparison with the size of the semiconductor light-emitting device 10 shown in FIG. 1.

Steps of manufacturing the semiconductor light-emitting device 70 are the same as the manufacturing steps shown FIGS. 5A to 6C. The same explanations will not be repeated.

As described above, the second embodiment includes the concave portion 72 in the substrate 71 to store the excess of the first translucent resin 73 in the concave portion 72, thereby enabling it to reduce variations in the chromaticity with a viewing direction and downsize the device 70 in comparison with the size of the semiconductor light-emitting device 10 shown in FIG. 1.

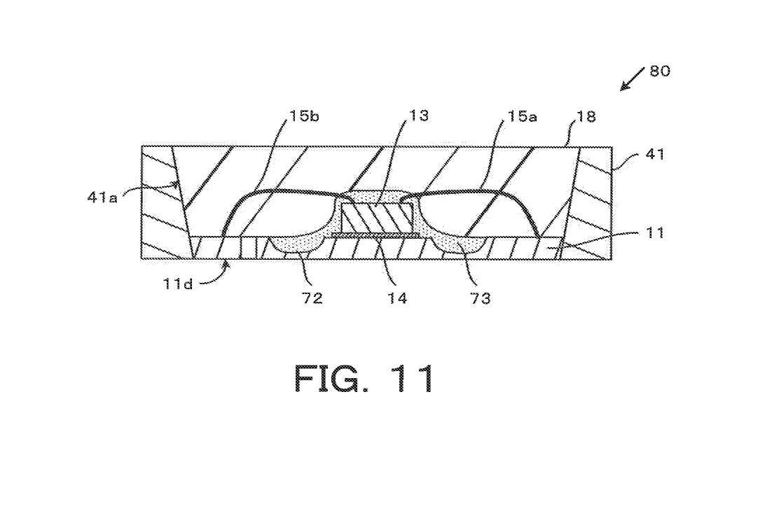

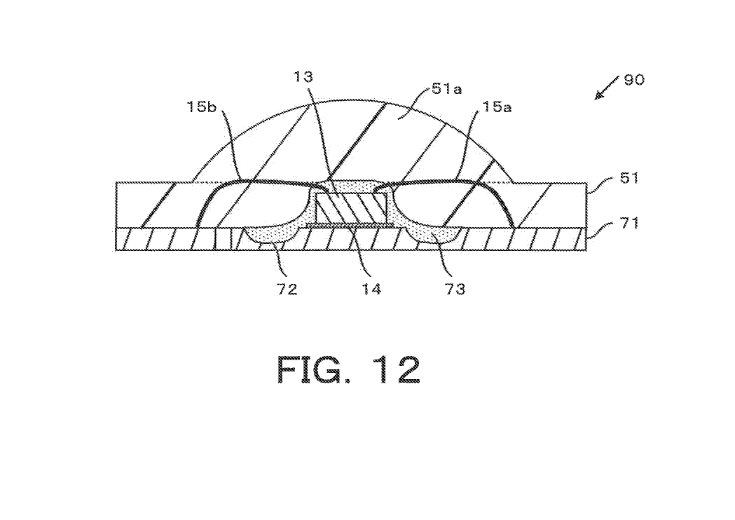

The semiconductor light-emitting device 70 of the second embodiment may be modified to emit light focused in one direction. FIG. 11 and FIG. 12 are sectional views showing semiconductor light-emitting devices capable of emitting light focused in one direction.

As shown in FIG. 11, a semiconductor light-emitting device 80 includes a case 41 with a mortar-like opening to serve as a reflector as well as the semiconductor light-emitting device 40 shown in FIG. 7.

As shown in FIG. 12, a semiconductor light-emitting device 90 includes the second translucent resin 51 with the dome-like convex portion 51a in the same way as the semiconductor light-emitting device 50 shown in FIG. 8. The semiconductor light-emitting device 90 enables it to downsize the device 90 in comparison with the size of the semiconductor light-emitting device 50 shown in FIG. 8.

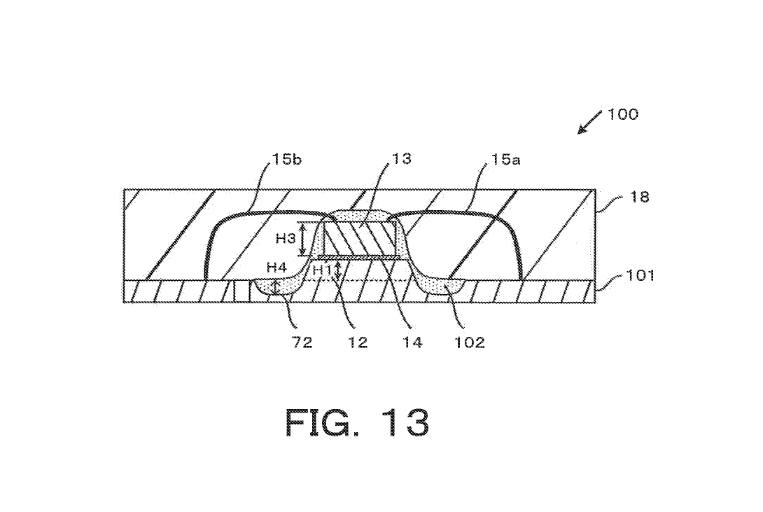

The second embodiment can also combine the concave portion 72 with the convex portion 12 shown in FIG. 1. FIG. 13 is a sectional view showing a semiconductor light-emitting device with a convex portion and a concave portion surrounding the convex portion.

As shown in FIG. 13, a semiconductor light-emitting device 100 includes a convex portion 12 and a concave portion 72 surrounding the convex portion 12. The semiconductor light-emitting element 13 is placed on the convex portion 12 with the adhesives 14.

The first translucent resin 102 containing a fluorescent body (not shown) covers the upper surface 13a and the side surface 13b of the semiconductor light-emitting element 13. An excess of the first translucent resin 102 extends from the slope of the convex portion 12 to the inside of the concave portion 72.

As a height difference (H1+H2) denoted by the sum of H1 and H2 becomes larger, the liquid translucent resin 31 shown in FIG. 6 obtains higher force to flow down to the inside of the concave portion 72. As a result, a skirt shape of the first translucent resin 102 can be improved to cover the side surface 13b of the semiconductor light-emitting element 13.

It is considered, therefore, that the thickness of the first translucent resin 102 covering the upper surface 13a of the semiconductor light-emitting element 13 becomes closer to the thickness of the first translucent resin 102 covering the side surface 13b of the element 13.

### Third Embodiment

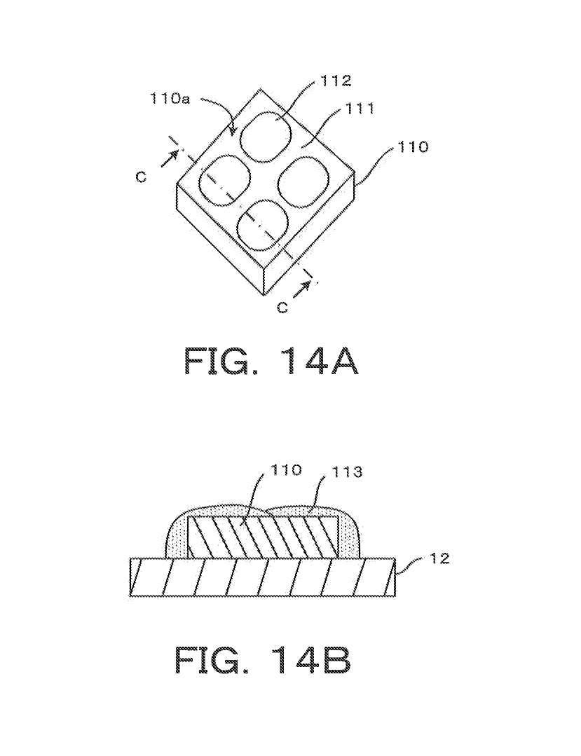

A semiconductor light-emitting element in accordance with a third embodiment will be described with reference to FIGS. 14A and 14B. FIGS. 14A and 14B are views showing a main portion of the semiconductor light-emitting element of the third embodiment. FIG. 14A is a perspective view. FIG. 14B is a sectional view cut along the C-C line in FIG. 14A, viewed from the arrows.

The same portions or the like will be denoted by the same reference numerals also in the third embodiment. The same explanations will not be repeated. The third embodiment differs from the first embodiment in that two different types of regions are alternately provided on the upper surface of the semiconductor light-emitting element in the third embodiment. Liquid translucent resin containing a fluorescent body easily flows over one of the two kinds of the regions. The liquid translucent resin hardly flows over the other.

As shown in FIG. 14A, the semiconductor light-emitting element 110 includes a lattice-shaped first region 111 and a second region 112 surrounded by the first region 111. Liquid translucent resin easily flows in the first region 111, and hardly flows in the second region 112.

The first region 111 and the second region 112 are different from each other in surface roughness, for example. The first region 111 has a smooth surface, and the second region 112 has a rough surface. The smooth surface has lower friction than the rough surface to cause liquid translucent resin to easily flow over the smooth surface.

When the surface roughness of the first region 111 is identical with that of the second region 112, liquid translucent resin dripped onto a semiconductor light-emitting element to round thereon by surface tension. As a result, the liquid translucent resin is thicker in the central portion of the semiconductor light-emitting element than in the circumference of the element, becoming convex.

Targeting the thickness of the liquid translucent resin in the central portion causes the circumference portion to be thinner than the target thickness. Targeting the thickness of the liquid translucent resin in the circumference portion causes the central portion to be thicker than the target thickness. Potting is limited in the capability thereof to uniform the thickness of the first translucent resin over the upper surface of the semiconductor light-emitting element.

In contrast, as shown in FIG. 14B, potting the semiconductor light-emitting element 110 with liquid translucent resin causes the liquid translucent resin to collect more in the second region 112 than in the first region 111. A small concave portion of the liquid translucent resin is formed in every second region.

Concave portions of liquid translucent resin become larger in the second region 112 as a result of an increase in the dripped amount of the liquid translucent resin, so that the adjacent concave portions attract each other to aggregate and collapse. This phenomenon causes the thicknesses of the central portion and the circumference of liquid translucent resin to approach each other. It is, therefore, possible to enhance the uniformity in the thickness of the first translucent resin 113 over the upper surface 110a of the semiconductor light-emitting element 110.

The first region 111 and the second region 112 will be specifically described as follows. When the upper surface 110a of the semiconductor light-emitting element 110 is a surface of a P-type GaN contact layer, and an ITO (Indium Tin Oxide) film is provided on the P-type GaN contact layer; the first region 111 is a surface of the ITO film, and the second region 112 is an uneven surface formed by etching the ITO film.

When the upper surface 110a of the semiconductor light-emitting element 110 is a surface of an N-type GaN layer; the first region 111 is a surface of the N-type GaN layer, and the second region 112 is an uneven surface formed on the N-type GaN layer by etching etc.

As described above, the first region 111 and the second region 112 are alternately provided on the upper surface 110a of the semiconductor light-emitting element 110 in the third embodiment. Liquid translucent resin easily flows in the first region 111, and hardly flows in the second region 112. As a result, the third embodiment has a merit that uniformity in the thickness is enhanced of the first translucent resin 113 on the upper surface 110 of the semiconductor light-emitting element 110.

In the above description of the embodiment, the first region 111 is lattice-shaped. Nevertheless, the shape of the first region 111 is not limited as long as the first region 111 and the second region 112 are alternately arranged.

### Fourth Embodiment

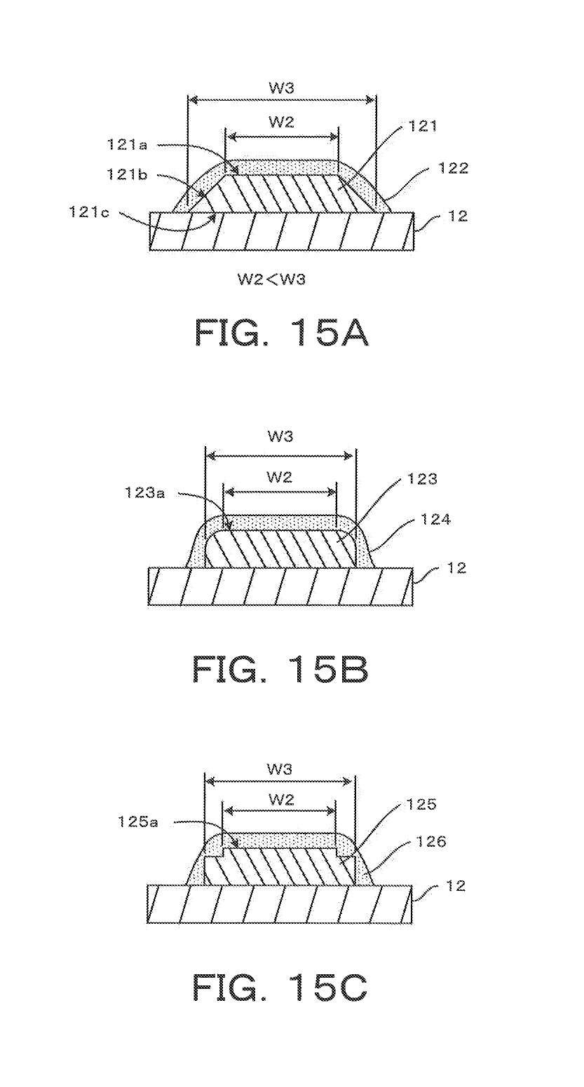

Semiconductor light-emitting devices in accordance with a fourth embodiment will be described with reference to FIGS. 15A to 15C, FIGS. 15A to 15C are sectional views showing three types of main portions of the semiconductor light-emitting devices in accordance with the fourth embodiment.

The same portions or the like will be denoted by the same reference numerals also in the fourth embodiment. The same explanations will not be repeated. The fourth embodiment differs from the first embodiment in that the lateral size of a semiconductor light-emitting element on the side in contact with a substrate of the element is larger than that on the side opposite to the substrate.

As shown in FIG. 15A, a semiconductor light-emitting element 121 of the fourth embodiment has an upper surface with a lateral size of W2 and a lower surface 121c with a lateral size of W3, and W2 is shorter than W3. The semiconductor light-emitting element 121 is trapezoidal in sectional shape.

When the angle between the upper surface and side surface of the element is 90° or smaller, the first translucent resin covering the element tends to become thinner at an edge where the upper surface and the side surface intersect with each other. Such a sharp edge with an angle of not more than 90° has caused the first translucent resin covering the element to be inhomogeneous in thickness.

In contrast, the semiconductor light-emitting element 121 has an obtuse angle at which the upper surface 121a and the side surface 121b intersect with each other. As a result of the obtuse angle, the first translucent resin 122 covering the semiconductor light-emitting element 121 is unlikely to be thin at the edge. The first translucent resin 122 covering the sloped side surface 121b is likely to have an improved skirt shape. The fourth embodiment, therefore, enables it to enhance homogeneity in the thickness of the first translucent resin 122 covering the semiconductor light-emitting element 121.

The semiconductor light-emitting element 121 with a trapezoidal section can be formed by cutting as sapphire substrate with a blade having a V-shaped section.

As described above, the fourth embodiment makes the size W2 of the upper surface 121a smaller than the size W1 of the lower surface 121c in the semiconductor light-emitting element 121. As a result, the fourth embodiment prevents the first translucent resin 122 covering the semiconductor light-emitting element 121 from becoming thinner at the corner of the element 121 to enhance homogeneity in the thickness of the first translucent resin 122.

In the above description of the fourth embodiment, the semiconductor light-emitting element with the size of the upper surface W2 smaller than the size of the upper surface W3 has a shape of a truncated pyramid, but the shape is not limited to the truncated pyramid.

FIG. 15B is a sectional view showing a semiconductor light-emitting element with chamfered edges. As shown in FIG. 15B, edges of the upper surface 123a are chamfered as to be round. The chamfered edges prevent the first translucent resin 124 covering the semiconductor light-emitting element 123 from becoming thinner at the edges. The edges of the upper surface 123a may be chamfered as to be straight.

FIG. 15C is a sectional view showing a semiconductor light-emitting element with a step. As shown in FIG. 15C, a semiconductor light-emitting element 125 includes a step on the side of the upper surface 125a. The step prevents the first translucent resin 126 covering the semiconductor light-emitting element 125 from becoming thinner at the edges. The more the number of steps, the more the semiconductor light-emitting element 125 approaches the element 121 shown in FIG. 15A.

The semiconductor light-emitting element 125 with a step on the side of the upper surface 125a is produced as follows. First, a sapphire substrate is cut to a depth of the certain thickness of the substrate with a thick blade to form a trench. Subsequently, the trench of the substrate is further cut to a depth of the full thickness of the substrate with a thin blade.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light-emitting device, comprising:
a substrate with a convex portion;
a semiconductor light-emitting element placed on the convex portion;
a frame body provided so as to surround the convex portion;
a first translucent resin covering an upper surface and a side surface of the element, extending from the convex portion to the frame body, and containing a fluorescent body; and
a second translucent resin provided on the substrate so as to bury the light-emitting element and the frame body.

2. The device according to claim 1, wherein
the convex portion is a submount substrate placed on the substrate.

3. The device according to claim 1, wherein
the upper surface of the light-emitting element includes a first region and a second region surrounded by the first region, a resin flows more easily in the first region than the second region.

4. The device according to claim 3, wherein
the second region has a rougher surface than the first region.

5. The device according to claim 1, wherein
a planer size of the upper surface of the light-emitting element is larger than the a planar size of the light-emitting element, on a side in contact with the substrate.

6. The device according to claim 1, wherein
the light-emitting element is an aggregate including two or more semiconductor light-emitting elements.

7. The device according to claim 1, wherein
the first translucent resin contains two or more kinds of fluorescent bodies.

8. The device according to claim 1, wherein
the second translucent resin contains a diffusion agent to diffuse light emitted from the light-emitting element and light emitted from the fluorescent body.

9. The device according to claim 1, wherein
the first translucent resin contains a diffusion agent to diffuse light emitted from the light-emitting element and light emitted from the fluorescent body.

10. The device according to claim 1, further comprising a case having an opening enlarging from the substrate toward the light-emitting element, the case provided on an outer circumference of the substrate, the light-emitting element arranged at a bottom of the case, the opening filled with the second translucent resin.

11. A semiconductor light-emitting device, the device comprising:
a substrate with a concave portion;
a semiconductor light-emitting element placed on a region surrounded by the concave portion;
a first translucent resin covering an upper surface and a side surface of the light-emitting element, extending within the concave portion, and containing a fluorescent body; and
a second translucent resin provided on the substrate so as to bury the light-emitting element.

12. The device according to claim 11, wherein
a convex portion is provided in a region surrounded by the concave portion; and
the light-emitting element is placed on the convex portion.

13. The device according to claim 11, wherein
the upper surface of the light-emitting element includes a first region and a second region surrounded by the first region, a resin flows more easily in the first region than the second region.

14. The device according to claim 13, wherein
the second region has a rougher surface than the first region.

15. The device according to claim 11, wherein
a planer size of the upper surface of the light-emitting element is larger than the a planar size of the light-emitting element on a side in contact with the substrate.

16. The device according to claim 11, wherein
the light-emitting element is an aggregate including two or more semiconductor light-emitting elements.

17. The device according to claim 11, wherein
the first translucent resin contains two or more kinds of fluorescent bodies.

18. The device according to claim 11, wherein
the second translucent resin contains a diffusion agent to diffuse light emitted from the element and light emitted from the fluorescent body.

19. The device according to claim 11, wherein
the first translucent resin contains a diffusion agent to diffuse light emitted from the light-emitting element and light emitted from the fluorescent body.

20. The device according to claim 11, further comprising a case having an opening enlarging from the substrate toward the light-emitting element, the case provided on an outer circumference of the substrate, the element arranged at a bottom of the case, the opening filled with the second translucent resin.
